(19) United States
(12) Patent Application Publication
(10) Pub. No.: US 2022/0352707 A1
(43) Pub. Date: Nov. 3, 2022

(54) ANALOG SIGNAL INPUT DEVICE FOR OPEN CIRCUIT DETECTION AND CONTROL SYSTEM

(71) Applicant: DENSO WAVE INCORPORATED, Chita-gun (JP)

(72) Inventors: Hiroshi ENDO, Chita-gun (JP); Riho UCHIZAWA, Chita-gun (JP)

(73) Assignee: DENSO WAVE INCORPORATED, Chita-gun (JP)

(21) Appl. No.: 17/729,379

(22) Filed: Apr. 26, 2022

(30) Foreign Application Priority Data
Apr. 28, 2021 (JP) 2021-075985
Sep. 10, 2021 (JP) 2021-147410

(51) Int. Cl. H02H 3/12; G05B 19/048

(52) U.S. Cl. CPC H02H 3/12; G05B 19/048; G05B 19/058

(57) ABSTRACT

A first input unit receives an analog signal from a pair of input terminals, to which a sensor is connected, as a differential input via a pair of first input lines between which a first resistor is interposed. The analog signal input device converts the analog signals read via the first input unit and a second input unit having a similar configuration into a multi-bit digital signal and outputs the digital signal. When a prescribed instruction is received, a current is supplied from one of the pair of first input lines to a power supply line, and it is determined that there an open circuit when the output of the second input unit obtained when the output of the first input unit has increased in response to the current supply from the current supply unit is equal to or larger than a predetermined threshold value.

### CROSS-REFERENCE TO RELATED APPLICATION

This application is based on and claims the benefit of priority from earlier Japanese Patent Application No. 2021-147410 filed Sep. 10, 2021 and Japanese Patent Applications No. 2021-075985 filed Apr. 28, 2021, the description of which is incorporated herein by reference.

### BACKGROUND OF THE INVENTION

### Technical Field of the Invention

The present disclosure relates to an analog signal input device that performs open circuit detection and a control system that uses the analog signal input device.

### Related Art

In a data logger that records the state of a control target or a control device such as a PLC that controls a control target in a prescribed sequence, an input device is connected. The input device is connected to a sensor for detecting the state of the control target, and amplifies and shapes signals from the sensor before finally converting them into digital signals.

The analog signals from the various sensors are converted into multi-bit digital signals that can be easily handled by the control device by an analog-to-digital converter (hereinafter also referred to as an ADC) provided in the input device. When the connection between the sensor and the input device is broken for some reason (this state is also called an open wire), the control device cannot accurately grasp the state of the control target. Therefore, it is necessary to detect the occurrence of an open wire. Various methods for detecting an open circuit have been proposed.

### SUMMARY

In an aspect of the present disclosure, there is provided an analog signal input device comprising:

a pair of input terminals to which a sensor is connected;

a pair of first input lines to which the pair of input terminals is connected;

a first input unit comprising a first resistor interposed between the pair of first input lines and receiving analog signals from the input terminals as a differential input via the pair of first input lines;

a pair of second input lines which branches from the first input lines and to which the pair of input terminals is connected via the first input lines;

a second input unit comprising the second resistor interposed between the pair of second input lines and receiving analog signals from the input terminals as a differential input via the pair of second input lines;

a signal output unit that receives the analog signals via the first and second input units individually, converts the analog signals into multi-bit digital signals, and outputs the digital signals;

a current supply unit that operates in response to a prescribed instruction to supply a current to one of the pair of first input lines; and

a decision unit that determines whether an output of the second input unit obtained when an output of the first input unit has increased in response to the current supply from the current supply unit is equal to or larger than a predetermined threshold value, and outputs a decision result.

### BRIEF DESCRIPTION OF THE DRAWINGS

In the accompanying drawings:

FIG. 1 is a general configuration diagram showing a control system including an analog signal input device of a first embodiment.

FIG. 2 is a circuit diagram showing specific configurations of input units.

FIG. 3 is an explanatory diagram showing a format of a communication packet for exchanging data between devices.

FIG. 4 is an explanatory diagram showing an example of a packet exchanged between devices.

FIG. 5 is a flowchart showing a flow rate measurement routine.

FIG. 6 is an explanatory diagram showing the route the current takes when an open circuit is detected.

FIG. 7 is a timing chart showing how the open circuit detection proceeds.

FIG. 8 is a flowchart showing an input signal checking routine.

FIG. 9 is a general configuration diagram showing a control system including an analog signal input device of a second embodiment.

FIG. 10 is a flowchart showing a flow rate measurement routine of the second embodiment.

FIG. 11 is a flowchart showing a flow rate measurement routine of a third embodiment.

FIG. 12 is a flowchart showing the contents of a third voltage acquisition and decision process added in the third embodiment.

FIG. 13 is a timing chart showing how the open circuit detection proceeds in the third embodiment.

### DETAILED DESCRIPTION OF THE PREFERRED EMBODIMENTS

In a data logger that records the state of a control target or a control device such as a PLC that controls a control target in a prescribed sequence, an input device that detects the state of the control target is connected. The input device is connected to a sensor for detecting the state of the control target, and amplifies and shapes signals from the sensor before finally converting them into digital signals. Some sensors may simply detect electrical signals such as voltage or current values, while others may detect various state quantities and output them as electric signals, such as a thermocouple and thermistor for detecting temperature, a flow meter for detecting flow, a strain gauge for detecting weight or strain, a magnetic sensor such as a Hall sensor for detecting magnetic flux, and an antenna probe for detecting radio wave intensity, frequency, and the like.

The analog signals from the various sensors are converted into multi-bit digital signals that can be easily handled by the control device by an analog-to-digital converter (hereinafter also referred to as an ADC) provided in the input device. When the connection between the sensor and the input device is broken for some reason (this state is also called an open wire), the control device cannot accurately detect the state of the control target. Therefore, it is necessary to detect the occurrence of an open wire. Various methods for detecting an open circuit have been proposed.

For example, JP 2012-008014 A discloses a configuration in which a minute current is supplied from the detector side to the sensor to detect wire breakage between the detector and the sensor. Further, as shown in the data sheet of A/D converter AD7124-4 manufactured by Analog Devices, Inc., It has also been proposed to provide the ADC itself with the function for detecting an open circuit. In such an ADC, a constant current source is prepared, and an open circuit detection process is performed in which, when the voltage between the input terminals to which a sensor is connected becomes indistinguishable from that measured when there is an open wire, a current from the constant current source is applied between the input terminals to detect an open circuit based on the behavior of the increase in the voltage between the input terminals. In general, the output impedance of a sensor or the like is low, whereas the input impedance of the input device to which the sensor is connected is high. Accordingly, the increase in the voltage between the input terminals caused by the constant current source differs depending on whether the connection with the sensor is normal or broken. This difference is identified to determine whether the connection between the sensor and the input device is broken.

However, such an open circuit detection method has problems that the accuracy of measurement using the sensor decreases due to the open circuit detection, and that the sensor output cannot be read when the open circuit detection is performed. For example, in the technique of JP 2012-008014 A, the variation in the current value caused by the minute current applied to the sensor affects the detection accuracy. In the technique of NPL 1, since a constant current source is connected between the input terminals while the open circuit detection process is being performed, the voltage between the input terminals rises regardless of whether there is an open circuit or not, and the sensor output values cannot be read until the open circuit detection is completed. Further, since the current supplied by the constant current source in the ADC of NPL 1 is about 0.5 to 4 μA, it takes time for the voltage between the input terminals to increase to a value that can be used to determine whether there is an open circuit, and the output of the sensor may not be measured for several seconds. In a manufacturing facility, being unable to read the sensor output for several seconds is often unacceptable.

Thus, the objective of the present disclosure is to provide an analog signal input device that can receive analog signals from a sensor without any difficulty during an open circuit detection in case that an open circuit is not occurred.

The present disclosure can be realized as the following embodiments or application examples.

(1) In a first aspect of the present disclosure, there provided is an analog signal input device comprising:

a pair of input terminals to which a sensor is connected;

a pair of first input lines to which the pair of input terminals is connected;

a first input unit comprising a first resistor interposed between the pair of first input lines and receiving analog signals from the input terminals as a differential input via the pair of first input lines;

a pair of second input lines which branches from the first input lines and to which the pair of input terminals is connected via the first input lines;

a second input unit comprising the second resistor interposed between the pair of second input lines and receiving analog signals from the input terminals as a differential input via the pair of second input lines;

a signal output unit that receives the analog signals via the first and second input units individually, converts the analog signals into multi-bit digital signals, and outputs the digital signals;

a current supply unit that operates in response to a prescribed instruction to supply a current to one of the pair of first input lines; and

a decision unit that determines whether an output of the second input unit obtained when an output of the first input unit has increased in response to the current supply from the current supply unit is equal to or larger than a predetermined threshold value, and outputs a decision result.

The principle of the open circuit detection performed by this analog signal input device is that, when the current supply unit supplies a current from one of the first input lines of the differential input to the power supply line (for example, the ground side line) in response to a prescribed instruction, this current flows through the first resistor interposed between the first input lines and increases the output of the first input unit, and, as a result, a voltage that differs depending on whether the connection between the input terminals and the sensor is broken is generated across the second input lines of the second input unit connected to the first input lines of the first input unit at the input terminals. A first resistor is interposed between the first input lines, and the voltage between the first input lines increases when a current is supplied by the current supply unit. This voltage causes a current to flow through the second input lines, and the voltage generated between the second input lines by this current differs depending on whether the internal resistance of the sensor is connected to the input terminals.

This allows an analog signal input device that converts an analog signal into a digital signal and outputs it to easily perform open circuit detection using a configuration including a first and second input units which receive analog signals as differential input. By having two input units which receive analog signals as differential input, the redundancy of the configuration for inputting analog signals is enhanced, and since the open circuit detection is performed by utilizing this, it is possible to reduce waste in the circuit configuration.

Further, the analog signal input device can receive analog signals from a sensor without any difficulty even during an open circuit detection in case that an open circuit is not occurred.

(2) In a second aspect of the present disclosure, there provided a control system comprising an analog signal input device that inputs an analog signal from a sensor, converts the analog signal into a digital signal, and outputs the digital signal, and a control device that is connected to the analog signal input device and controls a system, wherein

the analog signal input device includes
a pair of input terminals to which the sensor is connected,

a pair of first input lines to which the pair of input terminals is connected;

a first input unit comprising a first resistor interposed between the pair of first input lines and receiving analog signals from the input terminals as a differential input via the pair of first input lines;

a pair of second input lines which branches from the first input lines and to which the pair of input terminals is connected via the first input lines;

a second input unit comprising the second resistor interposed between the pair of second input lines and receiving analog signals from the input terminals as a differential input via the pair of second input lines;
a signal output unit that reads the analog signals via the first and second input units individually, converts the analog signals into a multi-bit digital signal, and outputs the digital signal to the control device,
a current supply unit that operates in response to an instruction from the control device and supplies a current to one of the pair of first input lines,
a decision unit that, in response to the current supply from the current supply unit, determines whether an output of the second input unit obtained when an output of the first input unit increases is equal to or larger than a predetermined threshold value, and
a decision result notification unit that outputs a result of the decision to the control device, and

the control device includes
an instruction output unit that outputs the instruction to the analog signal input device when at least one condition is satisfied, the at least one condition including a condition that a magnitude of the digital signal corresponding to a detection value of the sensor received from the analog signal input device cannot be distinguished from a detection value received when the sensor is not connected to the input terminals of the analog signal input device, and
a control signal output unit that outputs a control signal to the outside when the decision result received from the analog signal input device is an irregular state in which it cannot be determined that a connection between the sensor and the input terminals of the analog signal input device is not broken.

In this control system, the open circuit detection can be easily carried out with the analog signal input device, which is a device forming part of the control system, in a highly redundant configuration. Therefore, waste in the circuit configuration can be reduced. Further, the analog signal input device included in the control system and the control device for controlling the system can cooperate in detecting an open circuit, and the reliability as the control system can be improved.

Further, the control system can receive analog signals from a sensor without any difficulty even during an open circuit detection in case that an open circuit is not occurred.

Hereinafter, specific embodiments of a papermaking belt and a method for making a papermaking belt according to the present disclosure will be described in detail.

### A. First Embodiment

### (A1) Hardware Configuration:

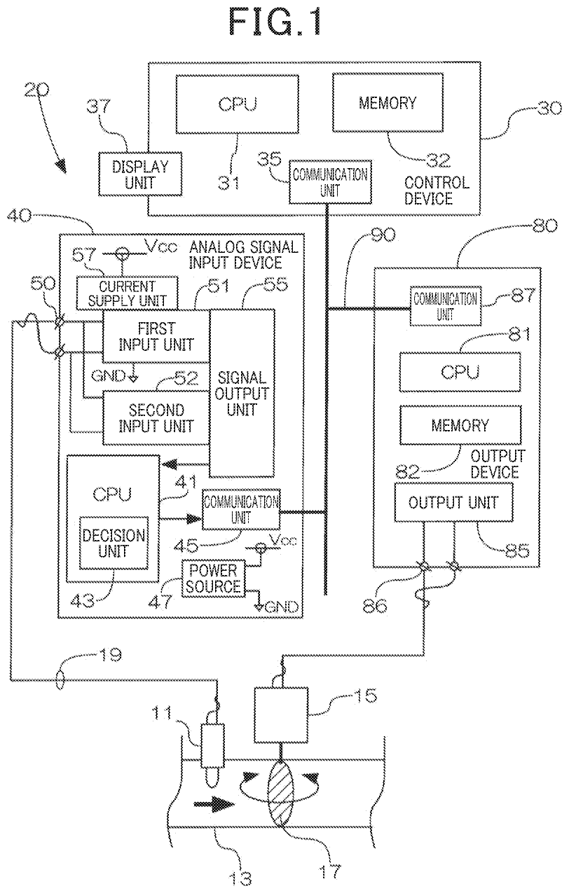

The configuration of a control system 20 including an analog signal input device 40 of the first embodiment is shown in FIG. 1. The control system 20 includes a control device 30 that has control over the processing of the entire system, an analog signal input device 40 that receives an input analog signal, and an output device 80 that drives elements such as an actuator. These components are connected via a communication line 90. In FIG. 1, only one analog signal input device 40 and one output device 80 are shown for one control device 30, but in reality, the control system 20 may include a plurality of input devices including an input device for receiving input digital signals as well as a plurality of output devices. In the present embodiment, the control device 30 is a PLC (Programmable Logic Controller).

In the first embodiment, a flow meter 11 is connected to the analog signal input device 40 as an example of a sensor. In this example, an analog signal from the flow meter 11 for measuring the flow rate of the fluid flowing through a pipe 13 in the system is received using the analog signal input device 40, and the flow rate of the fluid in the pipe 13 is measured. The analog signal input device 40 outputs a signal corresponding to the measured flow rate to the control device 30 via the communication line 90. The control device 30 calculates the control amount for the flow rate control valve 17 according to the flow rate, outputs it to the output device 80, and controls the actuator 15 using the output device 80.

The flow meter 11 and the input terminals 50 of the analog signal input device 40 are connected by a twisted pair cable 19 which is less susceptible to noise. This also applies to the connection of the actuator 15. Needless to say, other kinds of electric wires such as parallel cables may be used.

The control device 30 includes a well-known CPU 31, a memory 32, a communication unit 35, and a display unit 37. The control device 30 uses the communication unit 35 to communicate with the analog signal input device 40 and the output device 80 via the communication line 90, and controls various quantities including the flow rate of the fluid flowing through the pipe 13.

The analog signal input device 40 includes a pair of input terminals 50 to which the flow meter 11 is connected, and a first input unit 51 and a second input unit 52 connected to the pair of input terminals 50. The analog signal input device 40 also includes a signal output unit 55 which converts analog signals input from the first and second input units 51 and 52 into digital signals and outputs them, a current supply unit 57 which supplies a constant current to the first input unit 51, a CPU 41 which includes a built-in memory and has control over the entire analog signal input device 40, a decision unit 43 for the open circuit detection realized by a program executed by the CPU 41, a communication unit 45 which communicates with other devices via the communication line 90, and a power supply unit 47 which supplies power to the entire analog signal input device 40. In FIG. 1 and other figures, the positive voltage line Vcc side of the power supply line for the power output by the power supply unit 47 is indicated by a circle with a horizontal bar through it, and the grounding line GND side is indicated by an inverted triangle.

The CPU 41 is connected to the signal output unit 55 and the communication unit 45, and it reads the flow rate of the fluid in the pipe 13 measured by the flow meter 11 by reading the digital signals output from the signal output unit 55. In addition, the CPU 41 can transmit the result to the CPU 31 of the control device 30 via the communication unit 45, or perform open circuit detection in response to an instruction from the CPU 31 and inform the CPU 31 of the result. The analog signal input device 40 can handle an analog signal input to one input terminal 50 via the first and second input units 51 and 52 and the analog-to-digital converters ADC1 and ADC2, that is, it can handle the same analog signal using two hardware systems. The reason for handling one analog signal by two systems is to duplicate the hardware and increase redundancy so that the flow rate measurement can be continued by the other input system even if one input system falls, thereby improving the safety of the whole system. The configuration of the first input unit 51, the second input unit 52, and the signal output unit 55 will be described in detail later. Such duplication is performed on every input analog signals. However, the importance of the analog signals in the system may be ranked, and high-ranked analog signals may be duplicated to ensure the safety of the system, whereas analog signals that are not related to or weakly related to the safety may not be duplicated. Further, three or more copies may be created in order to enhance safety.

The output device 80 includes a CPU 81 which has control over the entire device, a memory 82 which stores programs and data necessary for the control, an output unit 85 which outputs drive signals to one or more external devices, and a communication unit 87 which performs communication via the communication line 90. The CPU 81 drives an external device, for example, the actuator 15 coupled to the flow rate control valve 17 via the output unit 85 by executing a program stored in the memory 82. The actuator 15 may be a motor, a solenoid, or any other appropriate device. Further, the CPU 81 can communicate with the control device 30 via the communication unit 87, receive an instruction from the control device 30, or notify the control device 30 of the current status of the output device 80.

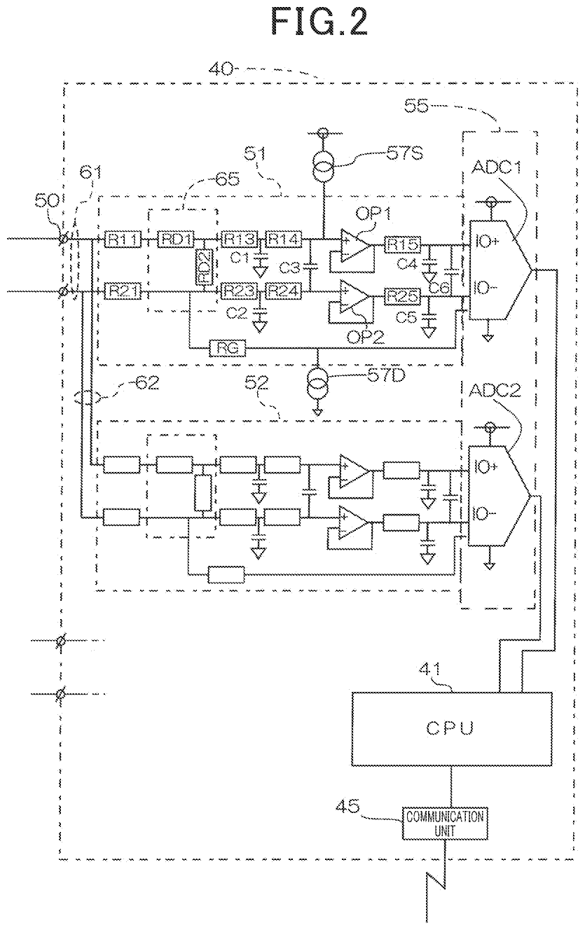

Next, referring to FIG. 2, the circuit configuration of the analog signal input device 40 will be described. Although the analog signal input device 40 is a module to which a plurality of analog signals can be input, only a configuration for processing one analog signal is shown in the drawing. The analog signal input device 40 is provided with a plurality of input terminals. A twisted pair cable 19 from the flow meter 11 shown in FIG. 1 is connected to the pair of input terminals 50 included in the plurality of input terminals. Inside the analog signal input device 40, two pairs of signal lines 61 and 62 are connected to the input terminals 50. These are hereinafter referred to as first input lines 61 and second input lines 62.

The first input unit 51 is connected to the first input lines 61, and the second input unit 52 is connected to the second input lines 62. The second input lines 62 is connected to the input terminal 50 via the first input lines 61. That is, the second input lines 62 is branched from the middle of the first input lines 1. Thus, the first input lines 61 and the second input lines 62 are connected.

The first input unit 51 and the second input unit 52 have exactly the same internal configuration in this embodiment. In the drawing, the boxes denoted by R represent resistors and the boxes denoted by C represent capacitors. The first input unit 51 includes resistors R11 and R21, a voltage divider circuit 65, resistors R13, R14, R23 and R24, operational amplifiers OP1 and OP2, and capacitors C1-C6. The voltage divider circuit 65 includes a first voltage divider resistor RD1 and a second voltage divider resistor RD2.

One of the pair of first input lines 61 is connected to, from the input side, the resistor R11, the first voltage divider resistor RD1 of the voltage divider circuit 65, the resistors R13 and R14 for noise removal, and the operational amplifier OP1. The output of the operational amplifier OP1 is connected to the positive input terminal I0+ of the analog-to-digital converter ADC1 via the resistor R15 for noise removal. The other first input line 61 is connected to, from the input side, the resistor R21, resistors R23 and R24 for noise removal, and an operational amplifier OP2. The output of the operational amplifier OP2 is connected to the negative input terminal I0− of the analog-to-digital converter ADC1 via the resistor R25 for noise removal. The second voltage divider resistor RD2 of the voltage divider circuit 65 is interposed between the connection point of the first voltage divider resistor RD1 and the resistor R13 and the other first input line 61. The voltage divider circuit 65 divides the voltage input to the input terminals 50 into RD1/(RD1+RD2) using two resistors, namely, the first and second voltage divider resistors RD1 and RD2. The reference signs RD1 and RD2 represent the resistance values of the respective resistors RD1 and RD2. The voltage divider circuit 65 is configured by using a resistor having a resistance value that is high enough with respect to the output impedance of a sensor (the flow meter 11 in this example), for example, about 100 kW. The division ratio of the voltage divider circuit 65 is not particularly limited and may be in the range of about 1:100 to 100:1. The division ratio may be determined from the voltage input to the input terminals 50 and the voltage that the signal output unit 55 can accept.

As shown in the drawing, the pair of signal lines from the flow meter 11 input to the input terminals 50 is connected to the pair of first input lines 61 of the first input unit 51. Since the voltage divider circuit 65 described above is interposed between the first input lines 61, when the voltage of the signal from the flow meter 11 exceeds the range of voltages that can be input by the first input unit 51, the voltage divider circuit 65 reduces the voltage of the signal from the flow meter 11 to a voltage within the range of voltages that can be input by the first input unit 51. When the voltage range of the signals from the flow meter 11 falls within the range of voltages that can be input by the first input unit 51, the voltage divider circuit 65 is not required. Therefore, the first voltage divider resistor RD1 is removed and the resistors R11 and R13 are short-circuited, whereas the second voltage divider resistor RD2 remains connected between the first input lines 61. The first input lines 61 are a differential input to the first input unit 51. The input signals from the flow meter 11 are therefore less susceptible to noise (differential noise) on the power supply line. The other one of the first input lines 61 forming the differential input is connected to a grounding line GND from the connection point between the resistors R21 and R23 via a grounding resistor RG and the analog-to-digital converter ADC1.

The capacitors C1 and C2 are interposed between the grounding line GND and the connection point of the resistors R13 and R14 for noise removal, and between the grounding line GND and the connection point of the resistors R23 and R24 for noise removal, respectively. The capacitor C3 is interposed on the side of the resistors R14 and R15 for noise removal closer to the input terminals of the operational amplifiers OP1 and OP2. Further, on the analog-to-digital converter ADC1 side of the resistors R15 and R25 for noise removal, the capacitors C4 and C5 are interposed between the respective lines and the grounding line GND, and a capacitor C6 is interposed between the input terminals I0+ and I0−. Further, the capacitors C1-C6 have a capacitance equal to or larger than a stray capacitance between the pair of the first input lines 61. By providing the capacitors C1-C6, since part of the current supplied from the current supply unit 57 is used to charge the capacitors C1-C6, the increase in the voltage between the first lines 61 will be delayed accordingly while facilitating the noise reduction.

The operational amplifiers OP1 and OP2 are both configured as voltage followers for increasing the input impedance. A current source 57S of the current supply unit 57 is connected to the input terminal + of the operational capacitor OP1, and a sink 57D of the current flowing from the current source 57S is connected to the connection point between the grounding resistor RG and the grounding line GND of the analog-to-digital converter ADC1. Since the input impedance of the operational amplifier OP1 is high, the current from the current source 57S flows through the circuit on the side on which the resistor R14 connected to the operational amplifier OP1 is located. How the current from the current supply unit 57 flows will be described later.

Since the second input unit 52 has the same internal configuration as the first input unit 51 described above except that the current supply unit 57 is not connected, it will not be described in detail. The second input unit 52 is connected to the pair of input terminals 50 via the pair of second input lines 62, and the outputs of the second input unit 52 are connected to the positive and negative input terminals I0+ and I0− of the analog-to-digital converter ADC2.

The current supply unit 57 operates in response to a prescribed instruction by CPU 31 or CPU 41 to supply a current to one of the pair of first input lines 61. Specifically, the current supply unit 57 includes the current source 57S which is connected to a signal line extended from one of the first input lines 61 and the sink 57 which is connected to a signal line extended from the other of the first input lines 61 and supplies constant current to the first input lines 61 from an external power source via the current source 57S. By externally supplying the constant current, relatively large current can be supplied and voltage between the first input lines 61 can be raised in a relatively short time. Accordingly, a time required for open circuit detection described later can be shortened.

As described above, the current supply unit 57 can supply a large amount of the constant current. Magnitude of the constant current is not particularly limited, however, the current supply unit 57 can supply constant current sufficiently enough to a combined resistance of a circuit formed by a supply of the current from the current supply unit 57, for example.

The output of the analog-to-digital converter ADC1 and the output of the analog-to-digital converter ADC2 are connected to the CPU 41. In the present embodiment, the analog-to-digital converters ADC1 and ADC2 and the CPU 41 are connected using serial communication, but a parallel connection having a predetermined number of bits may be used instead. The signal output unit 55 connected to the first and second input units 51 and 52 converts an analog signal from the flow meter 11 connected to the input terminals 50 into a digital signal at prescribed intervals, and outputs it to the CPU 41. The CPU 41 receives this and outputs it to the control device 30 via the communication unit 45.

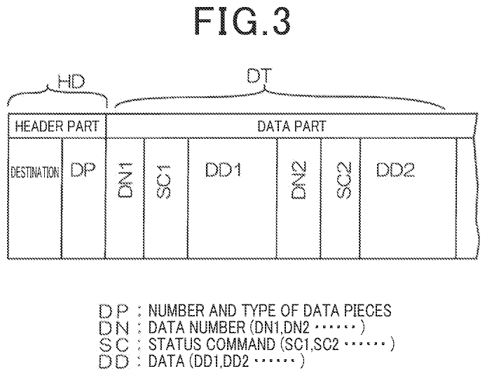

Data exchange between the devices is performed by communication via the communication line 90, including the data transmission from the analog signal input device 40 to the control device 30. An example of a bucket used for this communication is shown in FIG. 3. Since the packet configuration is agreed on between devices, packets can have any configuration. In the case that the communication line 90 is a so-called intranet (registered trademark) based on the Internet, the TCP/IP protocol may be used in the transport layer and the network layer, and the application layer may be agreed on between devices.

FIG. 3 is an explanatory diagram showing an example of a packet PT used in the present embodiment. The packet PT includes a header part HD and a data part DT. The header part HD includes the destination DS of the packet at its beginning, and it also includes a plurality of bits DP indicating the number and type of data pieces included in the packet PT at its end. The number of data pieces in the data part DT is information on how many data pieces DD each having a predetermined number of bits are included. The data type indicates whether each data piece DD is a text TX (8 bits), a numerical value Ns (8 bits), a numerical value Nw (16 bits), or a floating point numerical value Nf (32 bits).

The data part DT of each packet PT has a data number DN at its beginning, followed by a 3-bit status command SC and an 8-bit, 16-bit, or 32-bit data DD. Since the number and type of data pieces included in the data part DT differ for each packet PT, the packet PT length is variable. In the case of the analog signal input device 40, the data number DN corresponds to the number of the analog signals it is handling. For example, if the analog signal input device 40 is capable of inputting four analog signals, the data number DN1 indicates the analog signal connected to the input terminals 50.

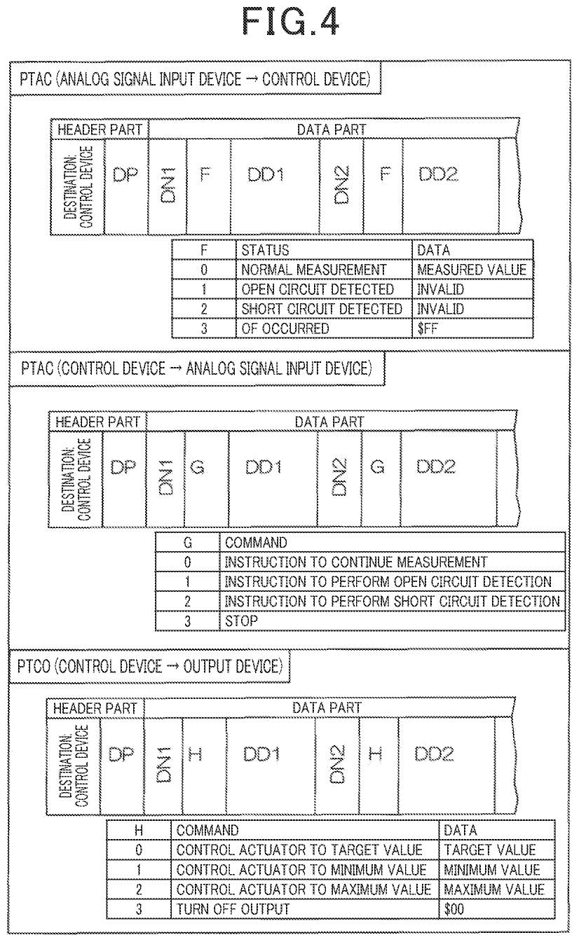

FIG. 4 shows three examples of such packets PT, namely, a packet PTAC transmitted from the analog signal input device 40 to the control device 30, a packet PTCA transmitted from the control device 30 to the analog signal input device 40, and a packed PTCO transmitted from the control device 30 to the output device 80. These packets each include a 3-bit status command SC, the contents of which differ depending on the type of packet. In the packet PTAC transmitted from the analog signal input device 40 to the control device 30, this status command SC is represented as a flag F. When flag F=0, the data indicates that the measurement is being performed normally, and the measured value is set in the data piece DD. When flag F=1, it indicates that a sensor open circuit has been detected, and the data piece DD is invalid. When flag F=2, it indicates that a short circuit between the input terminals 50 has been detected, and the data piece DD is invalid in this case as well. When flag F=3, it indicates that an overflow (OF) indicative of a measurement result exceeding the maximum value has occurred, and $FF is set in the data piece.

In the packet PTCA transmitted from the control device 30 to the analog signal input device 40, the status command SC is represented as a flag G. In this packet PTCA, the data pieces DD are basically invalid. Flag G=0 indicates an instruction to the analog signal input device 40 to continue the measurement. Flag G=1 is an instruction to the analog signal input device 40 to perform open circuit detection. Flag G=2 Is an instruction to the analog signal input device 40 to perform short circuit detection. Flag G=3 is an instruction to the analog signal input device 40 to stop the measurement.

In the packet PTCO transmitted from the control device 30 to the output device 80, the status command SC is represented as a flag H. In this packet PTCO, when flag H=0, it indicates that the instruction is to control the actuator 15 to a target value, and the data piece DD is the target value. When flag H=1, it indicates that the instruction is to control the actuator 15 to the minimum value, and the data piece DD is the minimum value of the control target. When flag H=2, it indicates that the instruction is to control the actuator 15 to the maximum value, and the data piece DD is the maximum value of the control target. When flag H=3, it indicates that the output to the actuator 15 should be turned off immediately, and the data piece DD is $00.

### (A2) Flow Rate Measurement Process:

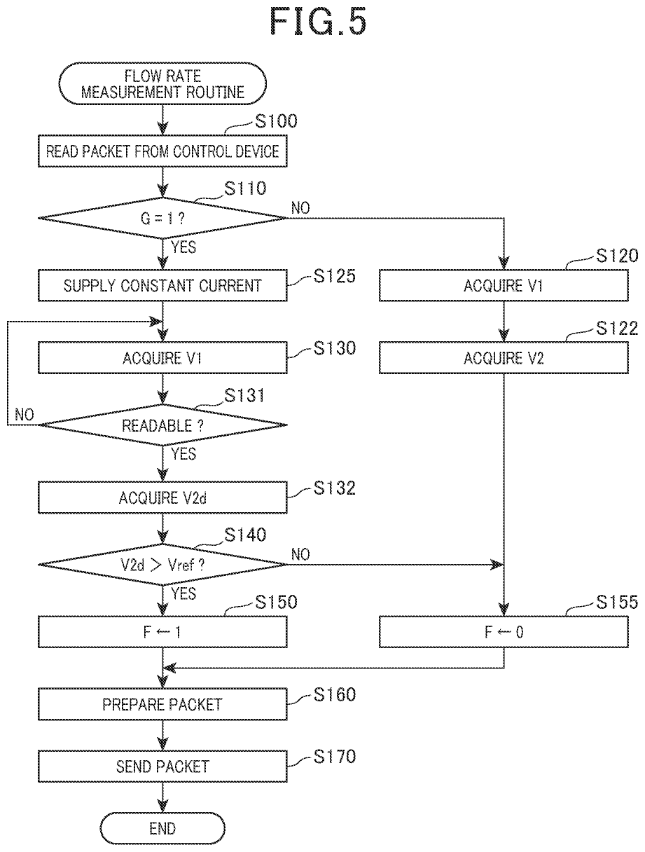

Based on the above circuit configuration and the method of communication between the devices, the flow rate measurement process performed by the analog signal input device 40 and the control device 30 will be described. FIG. 5 is a flowchart showing the flow rate measurement routine performed by the analog signal input device 40.

First, the flow rate measurement process performed by the analog signal input device 40 will be described. The process shown in FIG. 5 is repeatedly performed at predetermined intervals at which packets can be received via the communication line 90. When the process is started, first, the packet from the communication line 90 is read to check the destination of the packet. If it is determined that the packet is a packet from the control device 30 addressed to the analog signal input device 40, a process of reading the packet is performed (step S100). The contents of the packet received from the control device 30 by the analog signal input device 40 of the present embodiment are those of a packet PTCA shown in FIG. 4.

The analog signal input device 40 checks the data pieces of the received packet PTCA in order from the first data number DN1 included in the data part DT, especially the flag G which is the status command SC (step S110). As described above, if the value of the flag G is 1, this flag G indicates that the control device 30 has instructed the analog signal input device to carry out the open circuit detection. If the value of the flag G is not 1, the open circuit detection will not be performed, and the analog signal input device 40 converts the voltage signal from the flow meter 11 input via the first input unit 51 into a digital signal using the analog-to-digital converter ADC1 and reads it (step S120). Further, subsequently, the analog signal input device 40 converts the voltage signal from the flow meter 11 input via the second input unit 52 into a digital signal using the analog-to-digital converter ADC2 and reads it (step S122). In this embodiment, since the input system for converting one analog signal to a digital signal and reading it is duplicated, a signal from the same flow meter 11 is read by two systems. The voltage read from the first input unit 51 via the analog-to-digital converter ADC1 is referred to as a first voltage V1, and the voltage read from the second input unit 52 via the analog-to-digital converter ADC2 is referred to as a second voltage V2. The CPU 41 reads the first voltage V1 and the second voltage V2 individually (steps S120 and S122), then sets a value of 0 for the flag F as the status command SC used when transmitting the first voltage V1 and the second voltage V2 (step S155).

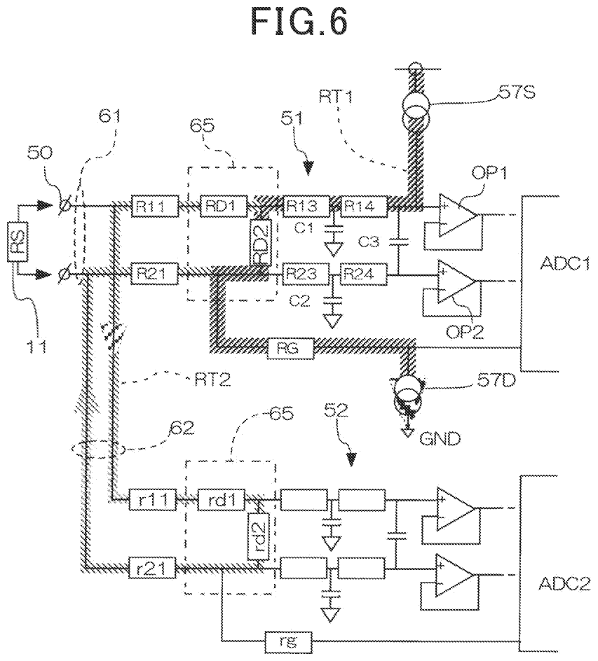

On the other hand, if the flag G has a value of 1 in step S110 (step S110: “YES”), the process of step S125 and the following steps are performed to carry out the open circuit detection. Although the process in which the control device 30 instructs the analog signal input device 40 to detect an open circuit using the flag G will be described in detail later, the instruction to perform the open circuit detection is given when the output of the flow meter 11 detected by the analog signal input device 40 cannot be distinguished from voltages detected when there is an open circuit. Therefore, the voltage of the signal input to the first input terminals 50 at the time the open circuit detection is started is substantially 0. The analog signal input device 40 starts the open circuit detection process of step S125 and the following steps in this state, and first, it causes the current supply unit 57 to supply a constant current from the current source 57S to the sink 57D (step S125). A route RT1 taken by the current at this time is shown in FIG. 6. The current flows from the current source 57S to the sink 57D via the resistors R14 and R13, the second voltage divider resistor RD2, and the grounding resistor RG. The sink 57D is connected to the grounding line GND of the entire device.

Since the current supply unit 57 can supply a current of several mA or more, although the capacitors C1 to C3 and the first input lines 61 have some stray capacitance, the constant current Ic supplied by the current supply unit 57 causes the first voltage V1 across the second voltage divider resistor RD2 to rise in a short time to

Vop=RD2·Ic.

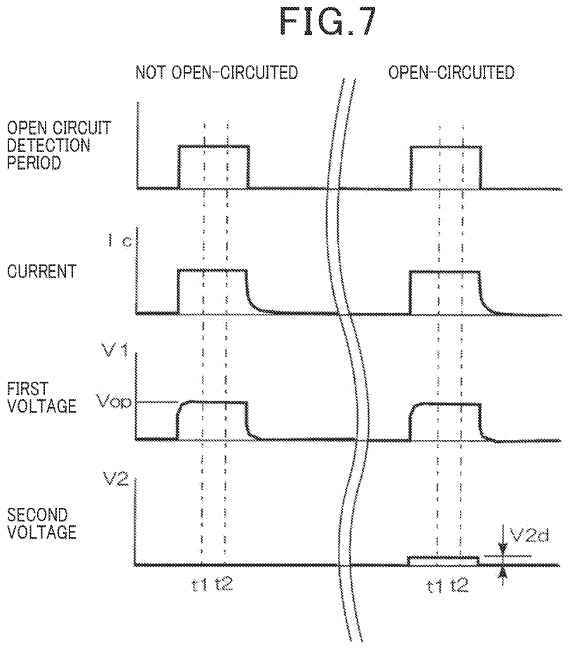

This is illustrated in FIG. 7. In the figure, a case where there is no open circuit, and a case where there is an open circuit (open wire) and the flow meter 11 is not connected to the first input terminals 50 are drawn side by side. In either case, the detection result of the analog-to-digital converter ADC1 obtained via the first input unit 51 quickly reaches the voltage Vop after the start of the open circuit detection period. Therefore, the first voltage V1 obtained via the first input unit 51 is read (timing t1 shown in FIG. 7), and when the first voltage V1 has reached the voltage Vop which is the voltage during open circuit detection, it is determined that now the voltage on the second input unit 52 side can be read (step S131: “YES”), and, in this state, the voltage on the second input unit 52 side is acquired via the analog-to-digital converter ADC2 at timing t2 shown in FIG. 7 (step S132). This voltage corresponds to the above-mentioned second voltage V2 if the open circuit detection is not being performed. However, the voltage of the signal input to the input terminals 50 when the open circuit detection is performed is almost 0, and the second voltage does not rise like the first voltage V1 even when there is an open circuit. Therefore, this is called a second minute voltage V2d.

The second minute voltage V2d is generated by the following circuit configuration. As shown in FIG. 6, when a constant current is supplied from the current supply unit 57 to perform the open circuit detection, the current flows along the path indicated by the route RT1, and a voltage of Vop is generated across the second voltage divider resistor RD2. Since the second input lines 62 of the second input unit 52 are connected in parallel to the first input lines 61 of the first input unit 51, the voltage across the second voltage divider resistor RD2 is applied to the second input lines 62 of the second input unit 52. In this case, the current flows along the route RT2 shown in FIG. 6. In FIG. 6, of the resistors of the second input unit 52, resistors involved in the route RT2 are denoted using the lowercase r as resistors r11 and r21, and first and second voltage divider resistors rd1 and rd2 so that they correspond with the resistors of the first input unit 51. Using these reference sings, the route RT2 can be specifically expressed as follows: first voltage divider resistor RD1->resistor R11->resistor r11->first voltage divider resistor rd1->second voltage divider resistor rd2->resistor r21->resistor R21.

If the flow meter 11 is correctly connected to the first input terminals 50 and the connection with the flow meter 11 is not broken, the internal resistance RS of the flow meter 11 is connected between the second input lines 62. Since the internal resistance RS of the flow meter 11 is relatively small, the current flowing through the route RT2 will be extremely small. Since the current flowing through the route RT2 is smaller than the constant current flowing through the route RT1, the second minute voltage V2d detected via the second input unit 52 is almost 0 when there is no open circuit. Needless to say, if the flow meter 11 outputs a valid signal that has measured the flow rate during the open circuit detection, the second minute voltage V2d becomes a voltage corresponding to this signal. This case is illustrated in the left column of FIG. 7.

On the other hand, if the connection between the flow meter 11 and the first input terminals 50 breaks for some reason and an open circuit occurs, the circuit in which the part from the first voltage divider resistor RD1 to the resistor R21 is connected in parallel with respect to the second voltage divider resistor RD2 is not formed. As a result, as compared with the case where there is no open circuit, the amount of current flowing through the second voltage divider resistor rd2 increases, and accordingly, the second minute voltage V2d detected via the second input unit 52 rises. This is illustrated in the right column of FIG. 7.

Therefore, whether the second minute voltage V2d read in step S132 is larger than a threshold value Vref is determined (step S140), and if it is, it is determined that there is an open circuit, and a value of 1 Is set for the flag F (step S150). If the second minute voltage is not larger than the threshold value, the process proceeds to step S155, and a value of 0 is set for the flag F. When the resistance value of the route RT1 from the current source 57S to the sink 57D is about 130 kW, the measured value of the second minute voltage V2d was larger than 25 mV when the connection between the flow meter 11 and the input terminals 50 was broken. Based on this, in the present embodiment, a value of about 20 mV is set as the threshold value Vref.

After performing the above processing, a packet for communication is prepared (step S160). Specifically, a data number DN for transmitting the data of the input signal connected to the input terminals 50, the value of the flag F as the status command SC, and the first and second voltages V1 and V2 as the data DD to be transmitted are prepared in the format of the packet PTAC shown in FIG. 4. When the answer is “NO” in step S140 and a packet for communication is prepared via the processing of step S155 (step S160), the first and second voltages V1 and V2 are set to 0. After that, this packet PTAC is transmitted via the communication unit 45 (step S170), and the flow rate measurement routine is temporarily terminated. Note that, as shown in FIG. 4, since the data is invalid when the flag F has a value of 1 or 2 in the packet PTAC, no data is included when an open circuit or a short circuit is detected.

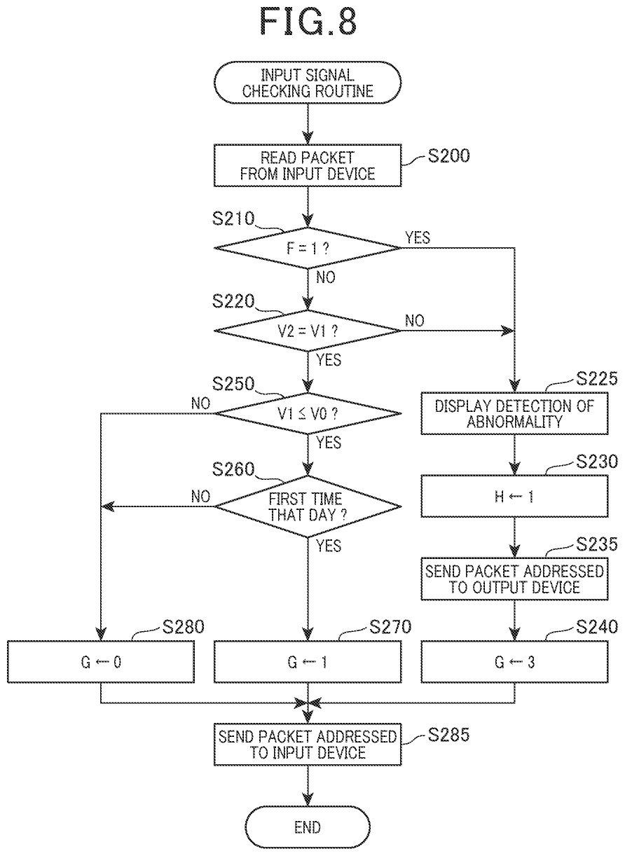

The packet thus transmitted is delivered via the communication line 90 and is received by devices connected to the communication line 90. When the control device 30 is constantly acquiring packets from the communication line 90 and the acquired packets are packets PTCA from the analog signal input device 40 addressed to the control device 30, the control device 30 executes the input signal checking routine shown in FIG. 8. When this process is started, first, the contents of the packet PTAC from the analog signal input device 40 is read (step S200). After that, a decision regarding the value of the flag F of the status command SC included in the packet PTAC is made (step S210).

If the value of the flag F is 0, that is, if the analog signal input device 40 has normally performed the measurement using the flow meter 11, the first and second voltages V1 and V2 included in the packet PTAC are read to see if they match (step S220). If it is determined in step S210 that the value of the flag F is 1, an open circuit has been detected. If the first and second voltages V1 and V2 do not match in step S220, it can be determined that there is a problem with the first or second input unit 51 or 52. Note that V1=V2 is a decision including a predetermined allowable range. If it is determined that an abnormality has occurred, the fact that an abnormality has been detected is displayed on the display unit 37 (step S225). Then, on the premise that it is an instruction to the output device 80, a packet PTCO for the output device 80 is formed setting a value of 1 for the flag H (step S230), and this packet PTCO is output to the output device 80.

As shown in FIG. 4, in the packet PTCO, the flag H of the status command SC having a value of 1 represents a command to control the actuator 15 to the minimum value. The data DD of this packet specifies the minimum value. Although the flow chart of this processing is not particularly shown, the output device 80 that has received this packet PTCO controls the actuator 15 to the minimum value indicated by the data DD as quickly as possible because the flag H=1. In this embodiment, controlling the actuator 15 to the minimum value means controlling the flow rate to the minimum, for example, 0. Such control is performed to control the system so that it is on the safe side.

For example, when the fluid flowing through the pipe 13 is a fluid that promotes a reaction, the promotion of the reaction is suppressed by minimizing the flow rate of the fluid so as to ensure the safety of the system. On the contrary, when the fluid is, for example, a refrigerant, the actuator 15 may be controlled to the maximum value as quickly as possible to prevent overheating and ensure system safety. Note that, when the value of the flag H is 0, normal control is performed in which the actuator 15 is controlled to the target value. The minimum value control performed when H=1 and the maximum value control performed when H=2 are the same as the normal control in that the actuator 15 is controlled to the minimum or maximum value, but differ in that, in the minimum value control and the maximum value control, the specified actuator is controlled to the minimum or maximum value as quickly as possible without controlling other actuators using time division. In this way, when it is determined that an abnormality has occurred, the setting of the flag H and the outputting of the packet PTCO are performed, and after that, a value of 3 is set for the flag G of the status command SC included in the packet PTCA to be output to the analog signal input device 40 (step S240).

On the other hand, if the answer is “YES” in step S220, that is, if the first and second voltages V1 and V2 match, it can be determined that the measurement by the analog signal input device 40 has been performed successfully, and subsequently, whether the first voltage V1 is equal to or smaller than a preset threshold value V0 is determined (step S250). This threshold value V0 is set at a low voltage that is difficult to distinguish from voltages obtained when there is an open circuit, several tens of millivolts in a practical example. When it is determined that the first voltage V1 is equal to or smaller than the threshold value V0, whether this is the first time it has been determined to be so that day is determined (step S260), and if it is, a value of 1 is set for the flag G as a preparation for giving an instruction to perform the open circuit detection (step S270). The value of this flag G is a flag referred to in the above-described flow rate measurement routine (FIG. 5, step S110) carried out in the analog signal input device 40. Since an open circuit does not occur frequently, it is sufficient if it is checked once a day on the days the control system 20 is utilized. Needless to say, the instruction to perform the open circuit detection may be given every time the first voltage V1 becomes equal to or smaller than the threshold value V0, or the instruction to perform the open circuit detection may be given once every several times it happens.

If the first voltage V1 is not equal to or smaller than the threshold value V0 (step S250: “NO”), or if it is determined to be so for the second time or more that day (step S260: “NO”), a value of 0 is set for the flag G (Step S280). After performing the setting of the flag G as described above (steps S240, S270, and S280), a packet PTCA for the analog signal input device 40 is prepared and transmitted to the analog signal input device 40 (step S285). This completes the input signal checking routine.

According to the analog signal input device 40 of the first embodiment described above, as well as the control system 20 including the device 40, the control device 30, and the output device 80, whether the connection between the flow meter 11 and the input terminals 50 is broken can be easily determined in the analog signal input device 40 capable of converting an analog signal into a digital signal and outputting the digital signal. By having two input units 51 and 52 that receive analog signals as differential input, the redundancy of the configuration for inputting analog signals is enhanced, and since the open circuit detection is performed by utilizing this, it is possible to reduce waste in the circuit configuration.

Further, since a current having a sufficient magnitude with respect to the circuit resistance is supplied from the current supply unit 57 used to carry out the open circuit detection, the time required for the open circuit detection can be reduced. Since an analog-to-digital converter ADC1 or ADC2 is provided for each of the two input units 51 and 52, the voltages of the two input units 51 and 52 can be measured almost simultaneously, and the open circuit detection can be completed in a short time in this respect as well. Moreover, when there is no open circuit, the second minute voltage V2d measured on the second input unit 52 side is the same as the second voltage V2 normally detected by the second input unit 52, which makes it possible to measure the magnitude of the analog signal from the flow meter 11 even while the open circuit detection is being performed. These features are particularly preferable when the control system 20 is an industrial PLC device. In case where the control system 20 is controlling a production line, it can be kept informed of the states of the sensors with no delay in grasping the state of the target. The quality of the product can be sufficiently ensured, and defective products will not be produced due to reasons such as the input of the analog signals being delayed.

Further, in the present embodiment, the control device 30 gives an instruction to perform the open circuit detection to the analog signal input device 40, and the frequency and timing of the open circuit detection performed by the analog signal input device 40 can be appropriately determined based on the operating situation of the entire control system 20. In the present embodiment, the open circuit detection is performed only when the voltage of the analog signals from the flow meter 11 detected by the first input unit 51 becomes equal to or smaller than the threshold value V0 (several tens of millivolts) for the first time each operating day of the control system 20. It is possible to perform the flow rate measurement thereafter after confirming that an open circuit has occurred. Further, if the analog signals from the flow meter 11 do not have a value that may be taken when there is an open circuit, the open circuit detection itself is not performed, so that no time is wasted for the open circuit detection.

In this control system 20, when an open circuit is detected, the actuator 15 that controls the physical quantity measured by the sensor (the flow meter 11 in this example) determined to be open-circuited is driven by the output device 80 so that the safety of the system to be controlled is enhanced. It is therefore possible to prevent the safety of the system from decreasing.

### B. Second Embodiment

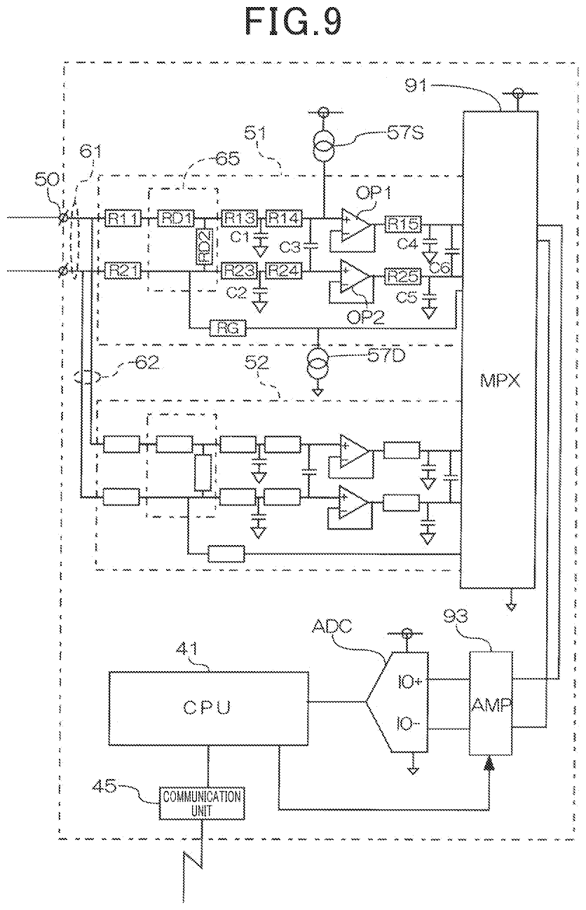

Next, an analog signal input device 40A according to the second embodiment and a control system that uses the device will be described. FIG. 9 is a configuration diagram of the analog signal input device 40A of the second embodiment. The control system as a whole has a configuration similar to that of the first embodiment shown in FIG. 1. The analog signal input device 40A of the second embodiment has substantially the same configuration as the analog signal input device 40 of the first embodiment, but differs from the first embodiment in that, instead of providing an analog-to-digital converter ADC1 or ADC2 for each of the first and second input units 51 and 52, a single analog-to-digital converter ADC is connected via a multiplexer (MPX) 71. The multiplexer 71 switches its output between the output of the first input unit 51 and the output of the second input unit 52 according to an instruction from the CPU 41 or at prescribed intervals. The output of the multiplexer 71 is input to the analog-to-digital converter ADC via an amplifier (AMP) 73 in which it is converted into a multi-bit digital signal. The converted digital signal is read by the CPU 41. The function of the analog-to-digital converter ADC is similar to those of the analog-to-digital converters ADC1 and ADC2 of the first example. The amplifier 73 is a variable gain amplifier whose gain is switched by a signal from the outside. In this embodiment, the CPU 41 changes the gain.

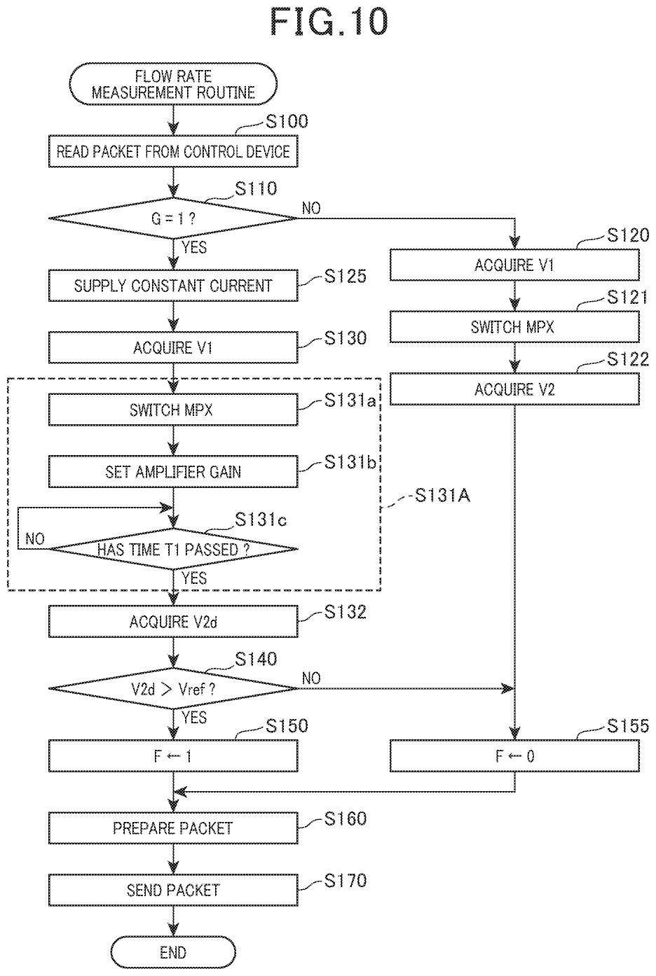

The CPU 41 of the analog signal input device 40A having the above configuration executes the flow rate measurement routine shown in FIG. 10. The basic processing of this routine is the same as that of the routine of the first embodiment shown in FIG. 5, but they differ in the following two points. One is that a procedure for switching the multiplexer 71 is provided between steps S120 and S122. The other is that step S131 of the first embodiment is replaced by a readability decision process 131A which includes step S131a for switching the multiplexer 71, step S131b for setting the gain of the amplifier 73, and step S131c for determining whether a time T1 has passed.

As described above, in the second embodiment, a single analog-to-digital converter ADC is provided for the first and second input units 51 and 52, and after reading the first voltage V1 (step S120), the multiplexer 71 is switched to switch the input of the analog-to-digital converter ADC from the output of the first input unit 51 to the output of the second input unit 52 (step S121). After the switching by the multiplexer 71 (step S121), the second voltage V2 is acquired (step S122).

In the readability decision process 131A, after acquiring the signal from the first input unit 51, that is, the first voltage V1 in the open circuit detection process, in order to prepare for the acquisition of the second minute voltage V2d, the multiplexer 71 is switched to the signal from the second input unit 52 (step S131a), and the gain of the amplifier 73 is increased (step S131b). Since the voltage detected by the second input unit 52 in the open circuit detection process is as small as about several tens of millivolts, increasing the gain facilitates the detection of the voltage and also improves the detection accuracy. After that, in the second embodiment, the second minute voltage V2d (step S132) is acquired after a time T1 has passed (step S131c). In the second embodiment, since the multiplexer 71 is switched, whether the first voltage V1 is high enough is not confirmed. Since it is possible to acquire in advance the time it takes for the first voltage V1 to become large enough when a constant current is supplied by the current supply unit 57, this time T1 is set, and the second minute voltage V2d is acquired after the time T1 has passed.

According to the second embodiment described above, the same effects as those of the first embodiment are obtained, and further, the circuit configuration can be simplified as it is unnecessary to provide an analog-to-digital converter ADC for each of the first and second input units 51 and 52. In addition, since the gain of the amplifier 73 is increased to read the second minute voltage V2d, the accuracy of open circuit detection can be improved.

### C. Third Embodiment

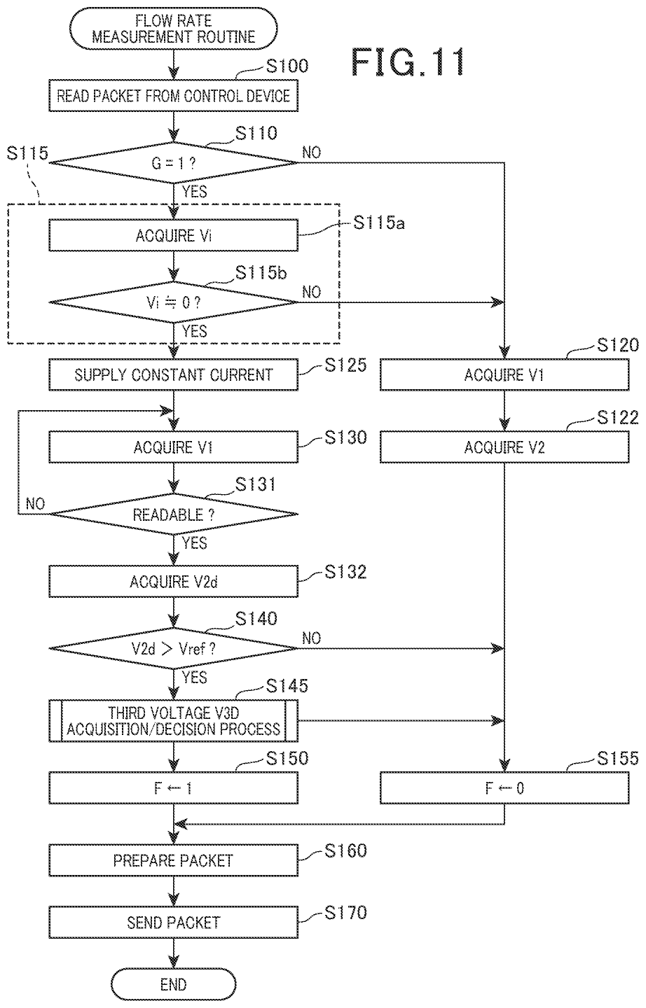

Next, the third embodiment will be described. The third embodiment has the same hardware configuration as the control system 20 including the analog signal input device 40 of the first embodiment. As the flow rate measurement process carried out by the analog signal input device 40, instead of the routine shown in FIG. 5, a flow rate measurement routine shown in FIG. 11 is performed. The basic processing of this routine is the same as that of the routine of the first embodiment shown in FIG. 5, but they differ in the following two points. One is that the former includes, after step S110, an initial voltage Vi acquisition and decision process (step S115) which branches into step S120 or S125. The other difference is that the former includes, after step S140, a third voltage V3d acquisition and decision process (step S145) which branches into step S150 or S155. The processing of the third embodiment will be described with particular focus on these steps S115 and S145.

Similarly to the first embodiment, first, a decision is made on the value of the flag G (step S110), and if it is determined that the value of the flag G is 0, that is, that an instruction to perform the open circuit detection is given, in the third embodiment, the initial voltage Vi acquisition and decision process (step S115) is performed. In this process, first, the voltage between the first input terminals 50 is acquired as an initial voltage Vi by using the first input unit 51 (step S115a). Subsequently, whether the initial voltage Vi Is substantially equal to 0 V is determined (step S115b). The phrase “substantially equal” as used herein means within ±10% of the value to be compared with. Needless to say, this range may be set in advance, and it may be, for example, ±5%. Note that, although the initial voltage Vi is acquired using the first input unit 51 in this example, it may be acquired using the second input unit 52.

The open circuit detection is often carried out in response to the flag G having a value of 1 when the flow meter 11 is not yet operating, such as when the system is being started. Therefore, normally, there is no output from the flow meter 11, and the initial voltage Vi should be substantially equal to 0 V. On the contrary, if the initial voltage Vi deviates from 0 V and it cannot be said that the two are substantially the same (step S115b, “NO”), it can be considered that the flow meter 11 is operating. The process proceeds to step S120 without performing the open circuit detection, and procedures such as acquiring the first and second voltages V1 and V2, and setting the flag F to 0 are performed. These procedures will not be described since they have already been described in connection with the first embodiment.

On the other hand, if it is determined that the initial voltage Vi is substantially equal to 0 V (step S115b, “YES”), as described in the first embodiment, a constant current is supplied by operating the current supply unit 57, more specifically, a constant current is supplied from the current source 57S to the sink 57D (step S125) to acquire the first voltage V1 and the second minute voltage V2d (steps S130 to S132). After that, whether the second minute voltage V2d is larger than the threshold value Vref is determined (step S140).

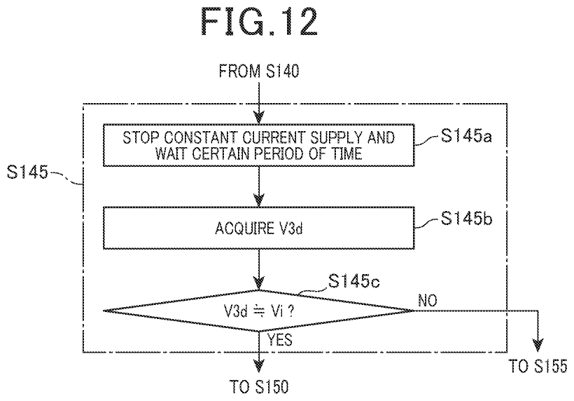

In the third embodiment, the processing of step S145 is further performed. As shown in FIG. 12, step S145 includes stopping the supply of the constant current and waiting a predetermined time (step S145a), acquiring the third voltage V3d using the second input unit 52 (step S145b), and determining whether the third voltage V3d is substantially equal to the first voltage V1 (step S145c). In step S145a, the current supply unit 57 is controlled to stop supplying the constant current and the process waits a predetermined time. The reason for waiting a predetermined time is because, due to the presence of capacitance components in the circuit such as the stray capacitance and the capacitor C3, the current flowing through the second voltage divider resistor rd2 may not immediately turn 0 and the third voltage V3d may take a valid value even after the constant current is stopped.

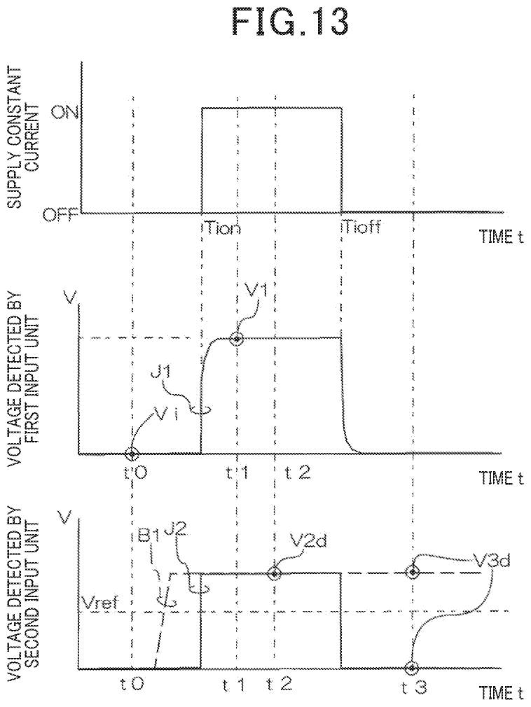

The timing of constant current supply by the current supply unit 57 is shown in the upper graph of FIG. 13. As described above, when the flag G is determined to be 1, the initial voltage Vi is acquired immediately after that. This timing is indicated as t0 in the figure. If the initial voltage Vi is substantially equal to 0 V (step S115b, “YES”), following this decision, the supply of the constant current is started at time Tion. This is a timing corresponding to the processing in step S125 of FIG. 11. After the supply of the constant current is started, the voltage across the second voltage divider resistor RD2 increases with the current flowing from the current source 57S to the sink 57D. This change in voltage is shown as a solid line J1 in the middle graph of FIG. 13. This change is the same as that of the first voltage shown in FIG. 7 in the first embodiment. At time t1 after time Tion at which the supply of the constant current is started, the first voltage V1 is acquired by the first input unit 51 (step S130). As described in detail in the first embodiment, this voltage Vop can be expressed as

Vop=RD2·Ic.

On the other hand, the voltage detected by the second input unit 52 in the case a constant current is supplied shows different behavior depending on whether there is an open circuit. The difference in voltage caused by the presence/absence of an open circuit is compared in FIG. 7. When a predetermined time has passed after acquiring the first voltage V1 so that the second minute voltage V2d can be read, at time t2, the second input unit 52 acquires the voltage across the second voltage divider resistor rd2 of the second input unit 52 as the second minute voltage V2d (step S132).

After that, the supply of the constant current is stopped at time Tioff, and after waiting a predetermined time (step S145a), the third voltage V3d is acquired by the second input unit 52 at time t3 (step S145b). Since the supply of the constant current from the current supply unit 57 is stopped, the measured third voltage V3d is normally the voltage obtained before supplying the constant current, that is, substantially 0. This is illustrated in FIG. 13 as a solid line J2. On the other hand, the voltage signal detected by the second input unit 52 when the wiring from the flow meter 11 to the first input terminals 50 is not broken, and a signal from the flow meter 11 happens to be input while the open circuit detection is being performed is indicated by a broken line B2. In the figure, the circles each indicate whether the voltage acquired at the corresponding one of time points t0 to t3 corresponds to the voltage on the solid line J1, J2, or the broken line B2.

After acquiring the third voltage V3d in this way (FIG. 12, step S145b), it is determined whether the third voltage V3d is substantially equal to the initial voltage Vi (step S145c). If they are substantially the same (step S145c, “YES”), it is considered that there is an open circuit, and the process proceeds to step S150 (FIG. 11). In step S150, a value 1 is set for the flag F which indicates the presence/absence of open circuit detection, and a packet is prepared and transmitted (steps S160 and S170). On the other hand, if it cannot be determined that they are substantially the same (FIG. 12, step S145c, “NO”), it is determined that the second minute voltage V2d exceeded the threshold value Vref (step S140, “YES”) not because there is an open circuit but because the signal sent from the flow meter 11 had a voltage (second minute voltage V2d) higher than the threshold value Vref. The flag F is set to 0 (FIG. 11, step S155), and a packet is prepared and transmitted (steps S160, S170). Note that, if the answer is “NO” in step S145c and a packet for communication is prepared via the processing of step S155 (step S160), the voltage acquired in step S130 is set as the first voltage V1 and the voltage (third voltage V3d) acquired in step S145b is set as the second voltage V2.

The case where it cannot be determined that the third voltage V3d is substantially equal to the initial voltage Vi will be described using FIG. 13. When there is an open circuit, the voltage detected by the second input unit 52 drops immediately after time Tioff at which the constant current supplied for the open circuit detection is stopped. This is because if no constant current is supplied by the current supply unit 57 when there is an open circuit, there will be no potential difference across the second voltage divider resistor rd2, and the third voltage V3d detected by the second input unit 52 at time t3 will be about the same as the initial voltage Vi (about 0 V) acquired by the first input unit 51 at time t0. On the other hand, when the third voltage V3d acquired by the second input unit 52 at time t3 is not about the same as the initial voltage Vi, the third voltage V3d is a voltage that cannot be generated when there is an open circuit even if it is smaller than the threshold value Vref. It is therefore determined that signals from the flow meter 11 are being detected.

According to the third embodiment described above, when the current supply unit 57 starts supplying a constant current in response to an instruction to perform the open circuit detection (G=1), and a voltage signal exceeding the threshold Vref is input from the flow meter 11, this will not be erroneously detected as an open circuit. This is because, in the present embodiment, the initial voltage Vi and the third voltage V3d are acquired before supplying the constant current (time t0) and after the supply is stopped (time t3), and the cause of the second minute voltage V2d acquired while the constant current is being supplied (time t2) can be determined by comparing them. If it is determined at the time t3 that V3d≈Vi, it is possible to determine whether the wiring from the flow meter 11 to the first input terminals 50 is broken. That is, in the third embodiment, it will not be erroneously detected that there is an open circuit when signals are being input from the flow meter 11. The other functions and effects are similar to those of the first embodiment.

It has been assumed that the hardware configuration of the third embodiment is the same as that of the first embodiment, but the same processing can be performed using the hardware configuration of the second embodiment. Further, to facilitate the understanding, the voltage detected by the second input unit 52 at time t2 of FIG. 13 when there is an open circuit is illustrated as the same as the voltage detected by the second input unit 52 at the same time when there is no open circuit and signals from the flow meter 11 are being input. However, a signal from the flow meter 11 does not always match the second minute voltage V2d generated by supplying the constant current. It is also possible that they are different.

In the above-described embodiments, the flag F takes one of the two values 1 (there is an open circuit) and 0 (it cannot be determined that there is an open circuit). However, the flag F may take a value other than 0 and 1 when the answer is “NO” in step S115b or when the answer is “NO” in step S145c. Further, the acquired voltages Vi, V1, V2, V2d, and V3d themselves may be transmitted as data to the control device 30 to determine whether there is an open circuit on the control device 30 side.

In the above-described embodiments, after starting the open circuit detection in response to the flag G having a value of 1, when it is determined that the conditions for open circuit detection are not satisfied, for example, when the answer is “NO” in step S140, the value of the flag F is set to 0 (step S155), and the process proceeds to the step of packet preparation (step S160). When it is determined that the conditions for open circuit detection are not satisfied, as with the case where the flag G is not 1, steps S120 and S122 may be executed to measure the first and second voltages V1 and V2, and the processing of step S155 and the subsequent steps may be carried out after that. Alternatively, a value other than 0 or 1 may be set for the flag F, that is, a value indicating that the conditions for open circuit detection were not satisfied even though it was attempted may be set, and a packet without voltage data may be prepared.

### D. Other Modes

(1) Such analog signal input devices 40 can also be implemented in the following configuration. For example, the analog signal input device may include:

a pair of input terminals to which a sensor is connected;

a first input unit that receives an analog signal from the input terminals as a differential input via a pair of first input lines between which a first resistor is interposed;

a second input unit that receives an analog signal from the input terminals as a differential input via a pair of second input lines between which a second resistor is interposed; a signal output unit that reads the analog signals via the first and second input units individually, converts the analog signals into multi-bit digital signals, and outputs the digital signals;

a current supply unit that operates in response to a prescribed instruction and supplies a current from one of the pair of first input lines to a power supply line; and

a decision unit that determines whether an output of the second input unit obtained when an output of the first input unit has increased in response to the current supply from the current supply unit is equal to or larger than a predetermined threshold value, and outputs a decision result.

This allows an analog signal input device capable of converting an analog signal into a digital signal and outputting it to easily perform open circuit detection using a configuration including a first and second input units that receive analog signals as a differential input. By having two input units that receive analog signals as differential input, the redundancy of the configuration for inputting analog signals is enhanced, and since the open circuit detection is performed by utilizing this, it is possible to reduce waste in the circuit configuration.

The principle of the open circuit detection is that the current supplied by the current supply unit from one of the first input lines of the differential input to the power supply line (for example, the ground side line) increases the output of the first input unit, whereas the voltage generated across the second input lines of the second input unit connected to the first input lines of the first input unit at the input terminals differs depending on whether the connection between the input terminals and the sensor is broken. A resistor and a capacitor are usually interposed between the first input lines for noise reduction and voltage division, and the voltage between the first input lines increases when a current is supplied by the current supply unit. This voltage causes a current to flow through the second input lines, and the voltage generated between the second input lines by this current differs depending on whether the internal resistance of the sensor is connected to the input terminals. The current supplied from the current supply unit is preferably a constant current so that amount of increase in voltage can be managed, but it does not need to be a constant current. Further, the current is preferably large enough with respect to the circuit resistance of the first input unit in order to reduce the time required for open circuit detection. Being able to reduce the open circuit detection time is particularly preferred in industrial applications. In facilities such as production lines, if there is a delay in understanding the state of the target or if the state cannot be known for a significant period of time, the product quality cannot be sufficiently ensured, and defective products may be produced. Such a situation can be avoided if quick open circuit detection is possible. If a condition is imposed that allows taking time for the open circuit detection, for example, if the open circuit detection is performed during the initialization process upon startup, the open circuit detection can be performed with a small current without the need to increase the current value enough with respect to the circuit resistance of the first input unit. The instruction for the current supply unit to start supplying current may be given as an externally-provided instruction for the open circuit detection operation, or may be a mere instruction given at predetermined intervals. Further, such an instruction may be given as an instruction to start a series of diagnostic actions for checking if the analog signal input device is operating properly. In this case, the open circuit detection may be performed as one of a series of operation checking actions.

The open circuit detection may be carried out on sensors that simply detect electrical signals such as voltage or current values, or sensors that detect various state quantities such as a thermocouple and thermistor for detecting temperature, a flow meter for detecting flow, a strain gauge for detecting weight or strain, a magnetic sensor such as a Hall sensor for detecting magnetic flux, and an antenna probe for detecting radio wave intensity, frequency, and the like. The sensor can be any sensor that detects a physical quantity and is connected to the input terminal of an analog signal input device by wire.

The sensor and the analog signal input device can be connected in any way as long as they are connected by wire at least at the connection part on the analog signal input device side, and part of the connection on the sensor side may be wireless. The wired connection part is preferably connected with a cable having high noise resistance such as a twisted pair cable. If noise resistance is not required, a common parallel wire cable or the like may be used. It is also possible to use a shielded cable to improve noise immunity.

(2) In such a configuration, each of the first and second resistors may be provided as a resistor forming part of a voltage divider circuit for adjusting a magnitude of a voltage of the analog signal from the sensor.

This makes it possible to use the resistor of the voltage divider circuit as a resistor at which the voltage rises in response to a current from the current supply unit, and therefore the circuit configuration can be simplified. In addition to or instead of the resistor of the voltage divider circuit, a resistor may be provided that causes the voltage between the first input lines of the first input unit to rise in response to a current from the current supply unit.

(3) In such a configuration, one or more capacitors having a capacitance equal to or larger than a stray capacitance of the first input lines may be interposed between each first input line and the power supply line.
This makes it possible to reduce the noise on the first input lines which are a differential input. When such capacitors are provided, since part of the current supplied from the current supply unit is used to charge the capacitors, the increase in the voltage between the first input lines will be delayed accordingly. Therefore, when such capacitors are provided, the amount of current supplied by the current supply unit may be determined taking into consideration the capacitance of the capacitors, and thus the delay in the voltage rise time.
(4) In such a configuration, the threshold value may be determined according to a voltage generated across the second resistor by a current flowing through the second input lines due to a voltage across the first resistor generated by the current supplied from the current supply unit when the sensor is not connected to the input terminals.

This makes it possible to determine the presence/absence of an open circuit by only comparing the generated voltage across the second resistor with the threshold value.

(5) In such a configuration, a communication unit that exchanges signals including the digital signals with a control device may be provided, and when the communication unit receives an instruction signal output by the control device which has determined that a magnitude of the digital signals included in the exchanged signal falls within a range of voltages that can be generated when a connection between the sensor and the input terminals is broken, the communication unit may give the prescribed instruction to the current supply unit to carry out open circuit detection.

The open circuit detection can be performed under the instruction of the control device when there is a possibility of an open circuit, which avoids the open circuit detection being performed unnecessarily. Note that, even when the magnitude of the digital signal included in the exchanged signal falls within a range of voltages that can be generated when a connection between the sensor and the input terminals is broken, the open circuit detection does not need to be carried out every time. It may be configured so that the open circuit detection is carried out only once every several times. In that case, the decision may be made by the control device or by the analog signal input device in response to an instruction from the control device. The open circuit detection does not need to be carried out every time the conditions are satisfied, and it may be performed once a day, for example, the first time the conditions are satisfied.

(6) In such a configuration, the decision unit may output the decision result to at least one of an administration device that administrates a control system connected to the analog signal input device and a presentation device that presents the decision result to a user.

If the decision result is output to the managing device, the administration device can use it to administrate the control system. On the other hand, if the decision result is presented to the user by the presentation device, it facilitates the user to take an appropriate action in response to the presentation of the decision result indicating the presence/absence of an open circuit. Needless to say, it is also possible to perform both. The administration device may be a control device that controls a control target in the control system, or may be a dedicated administration device, for example, a diagnosis computer. How to use the decision result regarding the presence/absence of an open circuit may be defined in the system design. The presentation of the decision result by the presentation device may be done by displaying it on a display or the like, or by notifying it by voice. Needless to say, only the fact that an open circuit has occurred may be presented, or information such as which sensor of which device is open-circuited and when the open circuit occurred may also be presented. It is also possible to just record the presence/absence of an open circuit.

(7) In such a configuration, the signal output unit may include a first analog-to-digital converter that converts the analog signals received via the first input unit into the digital signals, and a second analog-to-digital converter that converts the analog signals received via the second input unit into the digital signals.

This makes it possible to output the analog signal input to the first input unit and the analog signal input to the second input unit independently as digital signals, and the two signals can be output almost simultaneously. Therefore, the digital signals can be output in a short period of time even though the analog signals are multiplexed.

(8) In such a configuration, the signal output unit may include an analog-to-digital converter that selectively converts the analog signals received via the first and second input units into digital signals by time division.

The number of analog-to-digital converters can be reduced, and therefore the configuration can be simplified. For selective conversion to the digital signal by time division, a multiplier may be provided to switch between the output of the first input unit and the output of the second input unit. Needless to say, an individual switch, for example, a relay, an SSR, an analog switch, or the like may be separately provided and turned on/off exclusively. If the output stages of the first and second input units are provided with a configuration such as a tri-state buffer that can make the output high-impedance, the outputs may be coupled by a wired coupling. In this case, the output stage of the one of the first and second input units whose data is to be measured is switched from the high impedance state to the normal output state at the time of measurement.

(9) In such a configuration, the decision unit may

determine that a connection to the sensor is broken and output the decision result in a first case where it is determined that an output of the second input unit in response to the current supply from the current supply unit is equal to or larger than a predetermined threshold value, and

may not output the decision result that the connection to the sensor is broken in a second case where it is determined that the output of the second input unit in response to the current supply from the current supply unit is smaller than the predetermined threshold value.

Since the analog signal input device outputs the result of the decision on whether there is an open circuit, an external device can easily take necessary measures in response to this decision result.

(10) In such a configuration, in the first case, the decision unit may make a decision regarding an output of the second input unit after the current supply is stopped,

the decision unit may output the decision result that the connection to the sensor is broken when the output of the second input unit after stopping the current supply decreases to a level thereof before receiving the current supply, and

the decision unit may not output the decision result that the connection to the sensor is broken when the output of the second input unit after stopping the current supply does not decrease to a level thereof before receiving the current supply.

Since the analog signal input device outputs the result of the decision on whether there is an open circuit, an external device can easily take necessary measures in response to this decision result. In addition, it is possible to prevent erroneously determining that there is an open circuit when the second input unit receives an output from the sensor that exceeds the threshold value when performing the process of the open circuit detection.

(11) Other than the above aspects, the present invention can also be implemented as a control system. This control system includes an analog signal input device that inputs an analog signal from a sensor, converts the analog signal into a digital signal, and outputs the digital signal, and a control device that is connected to the analog signal input device and controls a system. In this control system, the analog signal input device may include
a pair of input terminals to which the sensor is connected,
a first input unit that receives an analog signal from the input terminals as a differential input via a pair of first input lines between which a first resistor is interposed,
a second input unit that receives an analog signal from the input terminals as a differential input via a pair of second input lines between which a second resistor is interposed,
a signal output unit that reads the analog signals via the first input unit and the second input unit individually, converts the analog signals into multi-bit digital signals, and outputs the digital signals to the control device,
a current supply unit that operates in response to a prescribed instruction from the control device and supplies a current from one of the pair of first input lines to a power supply line, a decision unit that, in response to the current supply from the current supply unit, determines whether an output of the second input unit obtained when an output of the first input unit increases is equal to or larger than a predetermined threshold value, and
a decision result notification unit that outputs a result of the decision to the control device, and

the control device may include
an instruction output unit that outputs the prescribed instruction to the analog signal input device when at least one condition is satisfied, the at least one condition including a condition that a magnitude of the digital signal corresponding to a detection value of the sensor received from the analog signal input device cannot be distinguished from a detection value received when the sensor is not connected to the input terminals of the analog signal input device, and
a control signal output unit that outputs a control signal to the outside when the decision result received from the analog signal input device is an irregular state in which it cannot be determined that a connection between the sensor and the input terminals of the analog signal input device is not broken.

This makes it possible to easily carry out, as a control system the open circuit detection with the analog signal input device in a highly redundant configuration. Therefore, waste in the circuit configuration can be reduced. Further, the analog signal input device included in the control system and the control device for controlling the system can cooperate in detecting an open circuit, and the reliability as the control system can be improved. In the analog signal input device included in this control system, two input units for inputting analog signals are combined to detect an open circuit, and the current supplied by the current supply unit can be increased. This reduces the time during which analog signals cannot be input, and analog signals can be read even while the open circuit detection process is being performed if there is no open circuit. Being able to reduce the open circuit detection time, or making it 0 is particularly preferable when the control system is an industrial PLC device. In facilities such as production lines controlled by an industrial PLC, if there is a delay in understanding the state of the target or if the state cannot be known for a significant period of time, the product quality cannot be sufficiently ensured, and defective products may be produced. Such a situation can be avoided if quick open circuit detection is possible, or analog signals can be input during the open circuit detection.

(12) In such a configuration, an output device connected to the control device may further be provided, and the output device may be

drivably connected to an actuator involved in control of a physical quantity whose behavior is detected by the sensor connected with the analog signal input device, and,

when the control signal is received from the control device, the output device may drive the actuator to control the behavior of the physical quality so that safety of the control system increases.

This improves the safety of the system when the connection with the sensor breaks.

(13) In such a configuration, devices constituting the control system may be connected to each other by a communication line, and at least the control device may exchange the digital signal, the prescribed instruction, the decision result, and the control signal with one or more other devices by communication via the communication line.

This facilitates the devices to cooperate via communication, and using this communication, the prescribed instruction for open circuit detection and the result of the detection process can be easily shared.

(14) In the above embodiments, the CPU which configures the decision unit, the CPU included in the output device or the CPU included in the control device is not limited to those in the above embodiments and can be replaced with any other appropriate semiconductor integrated circuit as long as required functions are exhibited. Examples of such semiconductor integrated circuit include arithmetic units other than CPUs, such as PLDs (Programmable Logic Devices), for example, FPGAs (Field Programmable Gate Arrays) and FPAAs (Field Programmable Analog Arrays), ASICs (Application Specific Integrated Circuits), MPUs (Micro Processing Units) and MCUs (Micro Controller Units). One of them can be employed alone, or two or more among them can be employed in combination.
(15) In the above embodiments, the control device may be any control device other than PLC.
(16) In the above embodiments, part of the configuration realized by hardware may be replaced with software. At least part of the configuration realized by software can also be realized by a discrete circuit configuration. Further, when part or all of the functions of the present disclosure are realized by software, the software (computer program) can be provided in the form of a computer-readable recording medium storing the software. A “computer-readable recording medium” is not limited to portable recording media such as flexible disks and CD-ROMs, but include internal storage devices provided in computers such as various RAMs and ROMs as well as external storage devices that are fixed to computers such as hard disks. That is, the term “computer-readable recording medium” has a broad meaning covering any recording medium on which data packets can be fixed rather than being temporarily stored.

The present disclosure is not limited to the above embodiments, and can be implemented in various configurations without departing from the spirit of the present disclosure. For example, the technical features of the embodiments corresponding to the technical features of the modes described in “SUMMARY” may be replaced or combined as appropriate to solve part or all of the above-described problems, or achieve part or all of the above-described effects. When a technical feature is not described as an essential feature herein, it can be removed as appropriate.

What is claimed is:

1. An analog signal input device comprising:
a pair of input terminals to which a sensor is connected;
a pair of first input lines to which the pair of input terminals is connected;
a first input unit comprising a first resistor interposed between the pair of first input lines and receiving analog signals from the input terminals as a differential input via the pair of first input lines;
a pair of second input lines which branches from the first input lines and to which the pair of input terminals is connected via the first input lines;
a second input unit comprising the second resistor interposed between the pair of second input lines and receiving analog signals from the input terminals as a differential input via the pair of second input lines;
a signal output unit that receives the analog signals via the first and second input units individually, converts the analog signals into multi-bit digital signals, and outputs the digital signals;
a current supply unit that operates in response to a prescribed instruction to supply a current to one of the pair of first input lines; and
a decision unit that determines whether an output of the second input unit obtained when an output of the first input unit has increased in response to the current supply from the current supply unit is equal to or larger than a predetermined threshold value, and outputs a decision result.

2. The analog signal input device according to claim 1, wherein each of the first and second resistors comprises a resistor forming part of a voltage divider circuit for adjusting a magnitude of a voltage of the analog signal from the sensor.

3. The analog signal input device according to claim 1, wherein the first input unit comprises one or more of capacitors having a capacitance equal to or larger than a stray capacitance between the pair of the first input lines.

4. The analog signal input device according to claim 1, wherein the first input unit comprises an operational amplifier as a voltage follower provided between the current supply unit and the signal output unit.

5. The analog signal input device according to claim 1, wherein the threshold value is determined according to a voltage generated across the second resistor by a current flowing through the second input lines due to a voltage across the first resistor generated by the current supplied from the current supply unit when the sensor is not connected to the input terminals.

6. The analog signal input device according to claim 1, further comprising
a communication unit that receives and transmits signals including the digital signals with a control device, wherein,
when the communication unit receives an instruction signal output by the control device which has determined that a magnitude of the digital signals included in the signal falls within a range of voltages that can be generated when a connection between the sensor and the input terminals is broken, the communication unit gives the prescribed instruction to the current supply unit to carry out open circuit detection.

7. The analog signal input device according to claim 1, wherein the decision unit outputs the decision result to at least one of an administration device that administrates a control system connected to the analog signal input device and a presentation device that presents the decision result to a user.

8. The analog signal input device according to claim 1, wherein the signal output unit includes a first analog-to-digital converter that converts the analog signals received via the first input unit into the digital signals, and a second analog-to-digital converter that converts the analog signals received via the second input unit into the digital signals.

9. The analog signal input device according to claim 1, wherein the signal output unit includes an analog-to-digital converter that selectively converts the analog signals received via the first and second input units into digital signals by time division.

10. The analog signal input device according to claim 1, wherein
the decision unit
determines that a connection to the sensor is broken and outputs the decision result in a first case where it is determined that an output of the second input unit in response to the current supply from the current supply unit is equal to or larger than a predetermined threshold value, and
does not output the decision result that the connection to the sensor is broken in a second case where it is determined that the output of the second input unit in response to the current supply from the current supply unit is smaller than the predetermined threshold value.

11. The analog signal input device according to claim 10, wherein,
in the first case, the decision unit makes a decision regarding an output of the second input unit after the current supply is stopped,
the decision unit outputs the decision result that the connection to the sensor is broken when the output of the second input unit after stopping the current supply decreases to a level thereof before receiving the current supply, and
the decision unit does not output the decision result that the connection to the sensor is broken when the output of the second input unit after stopping the current supply does not decrease to a level thereof before receiving the current supply.

12. A control system comprising an analog signal input device that inputs an analog signal from a sensor, converts the analog signal into a digital signal, and outputs the digital signal, and a control device that is connected to the analog signal input device and controls a system, wherein
the analog signal input device includes
a pair of input terminals to which the sensor is connected,
a pair of first input lines to which the pair of input terminals is connected;
a first input unit comprising a first resistor interposed between the pair of first input lines and receiving analog signals from the input terminals as a differential input via the pair of first input lines;
a pair of second input lines which branches from the first input lines and to which the pair of input terminals is connected via the first input lines;
a second input unit comprising the second resistor interposed between the pair of second input lines and receiving analog signals from the input terminals as a differential input via the pair of second input lines;
a signal output unit that reads the analog signals via the first and second input units individually, converts the analog signals into a multi-bit digital signal, and outputs the digital signal to the control device,
a current supply unit that operates in response to an instruction from the control device and supplies a current to one of the pair of first input lines,
a decision unit that, in response to the current supply from the current supply unit, determines whether an output of the second input unit obtained when an output of the first input unit increases is equal to or larger than a predetermined threshold value, and
a decision result notification unit that outputs a result of the decision to the control device, and
the control device includes
an instruction output unit that outputs the instruction to the analog signal input device when at least one condition is satisfied, the at least one condition including a condition that a magnitude of the digital signal corresponding to a detection value of the sensor received from the analog signal input device cannot be distinguished from a detection value received when the sensor is not connected to the input terminals of the analog signal input device, and
a control signal output unit that outputs a control signal to the outside when the decision result received from the analog signal input device is an irregular state in which it cannot be determined that a connection between the sensor and the input terminals of the analog signal input device is not broken.

13. The control system according to claim 12, further comprising
an output device connected to the control device, wherein
the output device
is drivably connected to an actuator involved in control of a physical quantity whose behavior is detected by the sensor connected with the analog signal input device, and,
when the control signal is received from the control device, the output device drives the actuator to control the behavior of the physical quality so that safety of the control system increases.

14. The control system according to claim 12, wherein devices constituting the control system are connected to each other by a communication line, and
at least the control device exchanges the digital signal, the prescribed instruction, the decision result, and the control signal with one or more other devices by communication via the communication line.
